(19) United States
(12) Patent Application Publication
(10) Pub. No.: US 2023/0103870 A1
(43) Pub. Date: Apr. 6, 2023

(54) BATTERY MODULE AND MANUFACTURING METHOD THEREOF

(71) Applicant: Acer Incorporated, New Taipei City (TW)

(72) Inventor: Shang-Hui Chen, New Taipei City (TW)

(73) Assignee: Acer Incorporated, New Taipei City (TW)

(21) Appl. No.: 17/736,109

(22) Filed: May 4, 2022

(30) Foreign Application Priority Data
Oct. 6, 2021 (TW) 110137197

(51) Int. Cl. H01M 50/516; H01M 50/519

(52) U.S. Cl. CPC H01M 50/516; H01M 50/519; H01M 2220/20

(57) ABSTRACT

A battery module includes a plurality of battery cores, a plurality of metal sheets, a circuit board and a solder. The metal sheets are electrically connected to the battery cores. Each of the metal sheets includes a metal bump, and the metal bump has an upper surface. The circuit board is disposed on the metal sheets and has a plurality of openings. The openings respectively expose the metal bump of each of the metal sheets. The metal bump divides each of the openings into a first cavity and a second cavity. The solder covers the upper surface of the metal bump of each of the metal sheets and each of the openings. The solder fills the first cavity, and there is an air gap in the second cavity.

### CROSS-REFERENCE TO RELATED APPLICATION

This application claims the priority benefit of Taiwan application serial no. 110137197, filed on Oct. 6, 2021. The entirety of the above-mentioned patent application is hereby incorporated by reference herein and made a part of this specification.

### BACKGROUND

### Field of the Disclosure

The present disclosure relates to a battery module and a manufacturing method thereof, and in particular, to a battery module applied to an electric bicycle and a manufacturing method thereof

### Description of Related Art

In order to enhance the aesthetic sense of the vehicle body as a whole, the battery module applied to the electric bicycle is normally hidden in the tube of the frame, so the appearance and shape of the battery module are similar to a long cylindrical body. Conventionally, the inner part of most battery modules is configured with a long wire to connect the metal nickel sheet and the printed circuit board. However, due to the thickness of the wire itself, it is not easy to be insert the wire into the battery module, and the price of the wire is not cheap.

Restricted by the diameter of the frame tube and the internal space of the battery module, at present, the metal nickel sheet and the printed circuit board inside the battery module are directly welded together to replace the wire for connecting the metal nickel sheet and the printed circuit board, thereby saving the space required inside the battery module. However, since the battery module needs to be subjected to vibration test, and the welding joint on the metal nickel sheet is easily separated from the metal nickel sheet after vibration, or the metal nickel sheet is prone to breakage, which affects the structural reliability of the battery module.

### SUMMARY OF THE DISCLOSURE

The present disclosure provides a battery module with better structural reliability.

The present disclosure further provides a method for manufacturing a battery module, which is used to manufacture the above-mentioned battery module, which may effectively reduce the welding time and the amount of solder used.

A battery module of the disclosure includes a plurality of battery cores, a plurality of metal sheets, a circuit board and a solder. The metal sheets are electrically connected to the battery cores. Each of the metal sheets includes a metal bump, and the metal bump has an upper surface. The circuit board is disposed on the metal sheets and has a plurality of openings. The openings respectively expose the metal bump of each of the metal sheets. The metal bump divides each of the openings into a first cavity and a second cavity. The solder covers the upper surface of the metal bump of each of the metal sheets and each of the openings. The solder fills the first cavity, and there is an air gap in the second cavity.

In an embodiment of the present disclosure, the upper surface of the metal bump is lower than a top surface of the circuit board.

In an embodiment of the present disclosure, the circuit board has a solder bonding area surrounding the periphery of each of the openings. The solder extends from the upper surface of the metal bump to the solder bonding area to cover each of the openings.

In an embodiment of the present disclosure, a surface of the solder is aligned with the top surface of the circuit board.

In an embodiment of the present disclosure, the metal bump has a first side and a second side opposite to each other. The upper surface connects the first side and the second side, and the solder covers the first side and exposes the second side.

In an embodiment of the present disclosure, each of the metal sheets further includes a connecting portion and a support portion. The support portion vertically connects the connecting portion and the metal bump. The connecting portion of each of the metal sheets is connected to the battery cores, and the circuit board is disposed on the support portion of each of the metal sheets.

In an embodiment of the present disclosure, the size of the first cavity is different from the size of the second cavity.

A manufacturing method of the battery module of the present disclosure includes the following steps. A plurality of battery cores and a plurality of metal sheets are provided. The metal sheets are electrically connected to the battery cores. Each of the metal sheets includes a metal bump, and the metal bump has an upper surface. A circuit board is disposed on the metal sheets and has a plurality of openings. The openings respectively expose the metal bump of each of the metal sheets. The metal bump divides each of the openings into a first cavity and a second cavity. A solder is formed to cover the upper surface of the metal bump of each of the metal sheets and each of the openings. The solder fills the first cavity, and there is an air gap in the second cavity.

In an embodiment of the present disclosure, the metal sheet includes a plurality of nickel sheets.

In an embodiment of the present disclosure, the solder includes tin-lead solder, lead-free solder or tin-silver-copper solder.

Based on the above, in the design of the battery module of the present disclosure, the metal bump of the metal sheet divides the opening of the circuit board into a first cavity and a second cavity, and the solder covers the upper surface of the metal bump and the opening. The solder fills the first cavity, and there is an air gap in the second cavity. In this way, when the battery module is subjected to a vibration test subsequently, the tensile force generated during the vibration will not break the metal bump and separate the metal sheets, so that the metal bump and the circuit board may be stably fixed together, and the battery module has better structural reliability.

In order to make the above-mentioned features and advantages of the present disclosure more comprehensible, the following embodiments are given and described in detail with the accompanying drawings as follows.

### BRIEF DESCRIPTION OF THE DRAWINGS

FIG. 1A to FIG. 1C are schematic views of a method for manufacturing a battery module according to an embodiment of the present disclosure.

FIG. 2 is a schematic top view of FIG. 1B.

### DESCRIPTION OF EMBODIMENTS

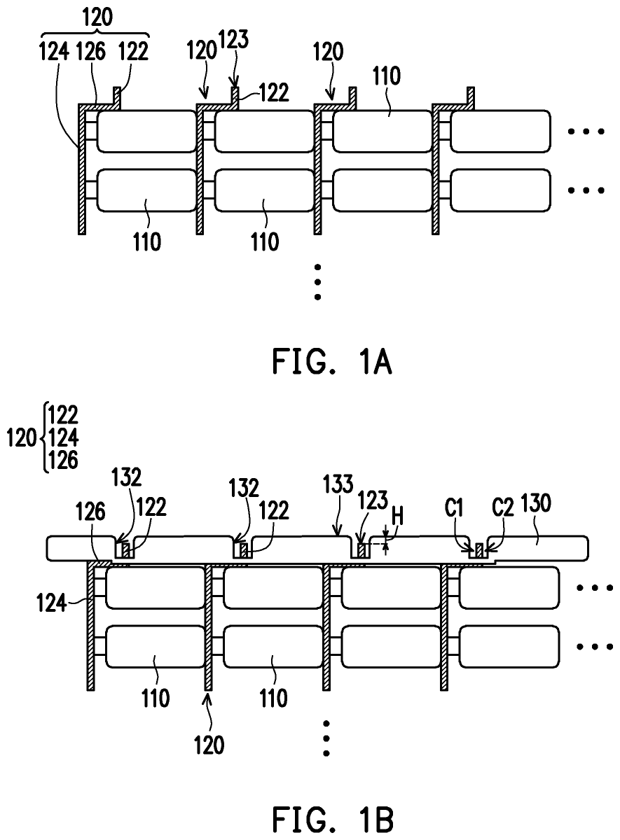

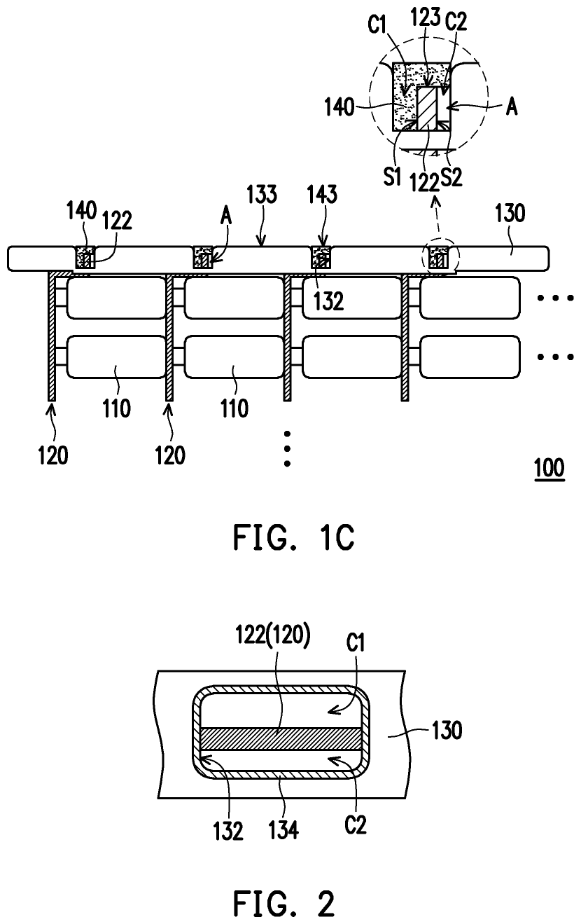

FIG. 1A to FIG. 1C are schematic views of a method for manufacturing a battery module according to an embodiment of the present disclosure. FIG. 2 is a schematic top view of FIG. 1B. Regarding the manufacturing method of the battery module of this embodiment, first, referring to FIG. 1A, a plurality of battery cores 110 and a plurality of metal sheets 120 are provided. The metal sheets 120 are electrically connected to the battery cores 110, and each of the metal sheets 120 has a metal bump 122, and the metal bump 122 has an upper surface 123.

More specifically, in this embodiment, each of the metal sheets 120 further includes a connecting portion 124 and a support portion 126, and the support portion 126 vertically connects the connecting portion 124 and the metal bump 122. Preferably, the metal bump 122, the connecting portion 124 and the support portion 126 are integrally formed. The metal bump 122 of each of the metal sheets 120 is configured to be welded with the circuit board 130 (please refer to FIG. 1B) configured subsequently. The connecting portion 124 of each of the metal sheets 120 is connected to the battery core 110, and the configuration of the metal sheet 120 and the battery core 110 may be connected in series, parallel or series-parallel mode according to requirements, the disclosure is not limited thereto. Here, the support portion 126 of the metal sheet 120 abuts against one side of the outermost battery core 110, and the metal sheet 120 is, for example, a nickel sheet, but the disclosure is not limited thereto.

Thereafter, please refer to FIG. 1B and FIG. 2 both, a circuit board 130 is arranged on the metal sheet 120. The circuit board 130 has a plurality of openings 132, and the openings 132 respectively expose the metal bump 122 of each of the metal sheets 120. Here, the metal bump 122 divides each of the openings 132 into a first cavity C1 and a second cavity C2, and the size of the first cavity C1 and the size of the second cavity C2 are different. Preferably, the first cavity C1 is larger than the second cavity C2.

More specifically, the circuit board 130 of the present embodiment is disposed on the support portion 126 of each of the metal sheets 120. There is a height difference H between the upper surface 123 of the metal bump 122 and the top surface 133 of the circuit board 130, and the upper surface 123 of the metal bump 122 is lower than the top surface 133 of the circuit board 130. That is, the height of the metal bump 122 is slightly lower than the thickness of the circuit board 130. Furthermore, as shown in FIG. 2, the circuit board 130 further has a solder bonding area 134 surrounding the periphery of each of the openings 132.

Finally, please refer to FIG. 1C and FIG. 2 both, a welding process is performed to form a solder 140 to cover the upper surface 123 of the metal bump 122 of each of the metal sheets 120 and the opening 130 of the circuit board 130, and the metal sheet 120 is welded to the circuit board 130. Specifically, the solder 140 extends from the upper surface 123 of the metal bump 122 to the solder bonding area 134 to cover each of the openings 132. In the meantime, a surface 143 of the solder 140 is approximately aligned with the top surface 133 of the circuit board 130. In particular, the solder 140 fills the first cavity C1, and there is an air gap A in the second cavity C2. Furthermore, after the solder 140 is turned into liquid when heated, the solder 140 generates a cohesive force and will not flow down easily like water. Since the first cavity C1 is larger than the second cavity C2, the soldering iron may easily enter the first cavity C1 for welding with the solder 140. For the second cavity C2, when welding is performed with a soldering iron, the upper surface 123 of the metal bump 122 and the solder bonding area 134 can be easily connected to form a plane by simply applying the soldering iron lightly thereon. Here, the solder 140 is, for example, tin-lead solder, lead-free solder, or tin-silver-copper solder, but the disclosure is not limited thereto. At this stage, the fabrication of the battery module 100 has been completed.

In terms of structure, please refer to FIG. 1C again. In this embodiment, the battery module 100 includes a battery core 110, a metal sheet 120, a circuit board 130 and a solder 140. The metal sheet 120 is electrically connected to the battery core 110. Each of the metal sheets 120 includes a metal bump 122, and the metal bump 122 has an upper surface 123. The circuit board 130 is disposed on the metal sheet 120 and has an opening 132. The openings 132 respectively expose the metal bump 122 of each of the metal sheets 120, and the metal bump 122 divides each of the openings 132 into a first cavity C1 and a second cavity C2. Here, the size of the first cavity C1 is different from the size of the second cavity C2, and the first cavity C1 is larger than the second cavity C2. The solder 140 covers the upper surface 123 of the metal bump 122 and each of the openings 132, and the surface 143 of the solder 140 is approximately aligned with the top surface 133 of the circuit board 130.

In particular, in this embodiment, the solder 140 fills the first cavity C1, and there is an air gap A in the second cavity C2. More specifically, the metal bump 122 has a first side S1 and a second side S2 opposite to each other, and the upper surface 123 connects the first side S1 and the second side S2. The solder 140 completely covers the first side S1 of the metal bump 122 and exposes the second side S2. Since the solder 140 extends from the upper surface 122 of the metal bump 120 to the solder bonding area 134 (please refer to FIG. 2) to cover the opening 132 and does not completely fill the second cavity C2, the weight of the solder 140 covered on the metal bump 122 may be reduced.

In the subsequent vibration test, since the first cavity C1 has been filled with the solder 140, while the second cavity C2 has not been filled with the solder 140 and has an air gap A, the tensile force generated during vibration will not pull the metal bump 122 away from the metal sheet 120, so that the metal bump 122 will not be separated from the metal sheet 120. Since the thickness of the metal sheet 120 is relatively thin, if the solder 140 completely fills the first cavity C1 and the second cavity C2, during the vibration test, the tensile force generated during the vibration will cause the metal bump 122 to break. Therefore, in this embodiment, the solder 140 only completely fills the first cavity C1 but not completely fills the second cavity C2, and there is an air gap A in the second cavity C2.

Under the circumstances, the metal bump 122 and the circuit board 130 may be stably fixed together, and the welding time during fabrication at the factory may be reduced, and the amount of solder used may be decreased as well.

To sum up, in the design of the battery module of the present disclosure, the metal bump of the metal sheet divides the opening of the circuit board into a first cavity and a second cavity, and the solder covers the upper surface of the metal bump and the opening. The solder fills the first cavity, and there is an air gap in the second cavity. In this way, when the battery module is subjected to a vibration test subsequently, the tensile force generated during the vibration will not break the metal bump and separate the metal sheets, so that the metal bump and the circuit board may be stably fixed together, and the battery module of the disclosure has better structural reliability. In addition, in the fabrication of the battery module of the present disclosure, since the second cavity is not completely filled with solder, the welding time and the amount of solder used in fabrication at factory may be reduced, and the manufacturing efficiency of the battery module of the present disclosure may be improved while the production costs may be reduced.

Although the present disclosure has been disclosed above by embodiments, it is not intended to limit the present disclosure. Anyone with ordinary knowledge in the technical field may make some changes and modifications without departing from the spirit and scope of the present disclosure. Therefore, the scope to be protected by the present disclosure shall be determined by the scope of the appended claims.

What is claimed is:

1. A battery module, comprising:
a plurality of battery cores;
a plurality of metal sheets, electrically connected to the plurality of battery cores, wherein each of the metal sheets comprises a metal bump, and the metal bump has an upper surface;
a circuit board, disposed on the plurality of metal sheets and having a plurality of openings, wherein the plurality of openings respectively expose the metal bump of each of the metal sheets, and the metal bump divides each of the openings into a first cavity and a second cavity; and
a solder, covering the upper surface of the metal bump of each of the metal sheets and each of the openings, wherein the solder fills the first cavity, and there is an air gap in the second cavity.

2. The battery module according to claim 1, wherein the upper surface of the metal bump is lower than a top surface of the circuit board.

3. The battery module according to claim 2, wherein the circuit board has a solder bonding area surrounding a periphery of each of the openings, and the solder extends from the upper surface of the metal bump to the solder bonding area to cover each of the openings.

4. The battery module according to claim 3, wherein a surface of the solder is aligned with the top surface of the circuit board.

5. The battery module according to claim 1, wherein the metal bump has a first side and a second side opposite to each other, and the upper surface connects the first side and the second side, and the solder covers the first side and exposes the second side.

6. The battery module according to claim 1, wherein each of the metal sheets further comprises a connecting portion and a support portion, the support portion vertically connects the connecting portion and the metal bump, the connecting portion of each of the metal sheets is connected to the plurality of battery cores, and the circuit board is disposed on the support portion of each of the metal sheets.

7. The battery module according to claim 1, wherein a size of the first cavity is different from a size of the second cavity.

8. A manufacturing method of a battery module, comprising:
providing a plurality of battery cores and a plurality of metal sheets, wherein the plurality of metal sheets are electrically connected to the plurality of battery cores, and each of the metal sheets has a metal bump, and the metal bump has an upper surface;
disposing a circuit board on the plurality of metal sheets, wherein the circuit board has a plurality of openings, the plurality of openings respectively expose the metal bump of each of the metal sheets, and the metal bump divides each of the openings into a first cavity and a second cavity; and
forming a solder to cover the upper surface of the metal bump of each of the metal sheets and each of the openings, wherein the solder fills the first cavity, and there is an air gap in the second cavity.

9. The manufacturing method of the battery module according to claim 8, wherein the plurality of metal sheet comprise a plurality of nickel sheets.

10. The manufacturing method of the battery module according to claim 8, wherein the solder comprises a tin-lead solder, a lead-free solder or a tin-silver-copper solder.
